(19) United States
(12) Patent Application Publication
(10) Pub. No.: US 2009/0200685 A1
(43) Pub. Date: Aug. 13, 2009

(54) Electronic packaging method and apparatus

(75) Inventor: Li-chih Fang, Hsinchu (TW)

Correspondence Address: Eschweiler & Associates LLC;National City Bank Building, 629 Euclid Avenue, Suite 1000, Cleveland, OH, 44114, US

(73) Assignee: Powertech Technology Inc., Hsinchu (TW)

(21) Appl. No.: 12/194,182

(22) Filed: Aug. 19, 2008

(30) Foreign Application Priority Data
Feb. 7, 2008 (TW) 97124948

(51) Int. Cl. H01L 23/52; H01L 21/00

(52) U.S. Cl. 257/782; 438/113; 257/E21.001; 257/E23.141

(57) ABSTRACT

The present invention utilizes a panel substrate as the packaging substrate carried by a working susceptor. Packaging devices are hung in the nearby of the working susceptor and moved by robot arms to the working susceptor, whereby the problems of substrate warpage and substrate transportation are overcome. Further, identical or different packaging steps can be simultaneously performed in different areas of a panel substrate, whereby the cost is reduced and the product yield is promoted.

### BACKGROUND OF THE INVENTION

1. Field of the Invention

The present invention relates to an electronic packaging method and apparatus, particularly to an electronic packaging method and apparatus using a panel substrate.

2. Description of the Related Art

Generally, the substrate manufacturer slices panel substrates into strip substrates and then delivers the strip substrates to the package manufacturer for the succeeding processes. The package manufacturer uses the strip substrates to carry chips in the chip packaging processes. Constrained by the existing process devices, the package manufacturer can only adapt the packaging processes to the packaging substrates in form of a strip. However, the prior art has problems in working area, substrate warpage and substrate transportation. Thus, the productivity is limited.

### SUMMARY OF THE INVENTION

One objective of the present invention is to provide an electronic packaging method and apparatus, which can adopt a panel substrate as the packaging substrate for package processes, whereby the cost is reduced and the product yield is increased, and whereby the abovementioned problems are overcome.

One objective of the present invention is to provide an electronic packaging method and apparatus, wherein a panel substrate is carried by a working susceptor, and wherein the packaging devices are hung in the nearby of the working susceptor and moved by robot arms to the working susceptor, whereby the problems of substrate warpage and substrate transportation are overcome.

One objective of the present invention is to provide an electronic packaging method and apparatus, wherein identical or different packaging steps can be simultaneously performed in different areas of a panel substrate.

To achieve the abovementioned objectives, one embodiment of the present invention discloses an electronic packaging method comprises the following steps: loading a substrate on a working susceptor; moving a chip attach device to the working susceptor to attach a plurality of chips onto the substrate; moving a wire-bonding device to the working susceptor to electrically connect the chips to the substrate via a plurality of wires; moving a molding device to the working susceptor to encapsulate the chips and wires; and moving a singulation device to the working susceptor to singulate the substrate into a plurality of packages.

Another embodiment of the present invention discloses an electronic packaging apparatus comprises a working susceptor used for carrying a substrate; a chip attach device mounted by hanging and moved to the working susceptor to attach a plurality of chips onto the substrate; a wire-bonding device mounted by hanging and moved to the working susceptor to electrically the chips to the substrate via a plurality of wires; a molding device mounted by hanging and moved to the working susceptor to encapsulate the chips and wires; and a singulation device mounted by hanging and moved to the working susceptor to singulate the substrate into a plurality of packages.

### BRIEF DESCRIPTION OF THE DRAWINGS

FIG. 1 is a flowchart of an electronic packaging method according to one embodiment of the present invention; and

FIG. 2 is a diagram schematically showing an electronic packaging apparatus according to another embodiment of the present invention.

### DETAILED DESCRIPTION OF THE INVENTION

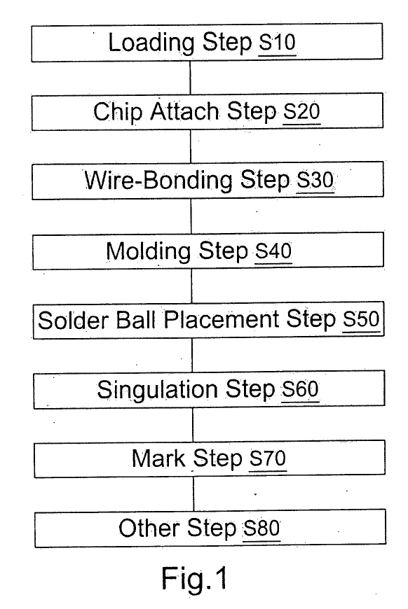

Referring to FIG. 1, FIG. 1 is a flowchart of an electronic packaging method according to one embodiment of the present invention. Firstly, a substrate is loaded on a working susceptor (S10, a loading step), and the substrate may be a panel substrate. Next, a chip attach device, such as a glue dispenser and a chip gripper, is moved to the working susceptor to attach a plurality of chips onto the substrate (S20, a chip attach step). Next, a wire-bonding device is moved to the working susceptor to electrically connect the chips to the substrate via a plurality of wires (S30, a wire-bonding step).

Next, a molding device is moved to the working susceptor to encapsulate the chips and wires (S40, a molding step). Next, a singulation device is moved to the working susceptor to singulate the substrate into a plurality of packages (S60, a singulation step). Each of the abovementioned chip attach device, wire-bonding device, molding device and singulation device is mounted by hanging and moved to the working susceptor by the robot arm. In another embodiment, the electronic packaging method of the present invention further comprises a mark step (S70), wherein a mark device is mounted by hanging and moved by the robot arm to the working susceptor to mark the packages.

In one embodiment, before the singulation step, the electronic packaging method further comprises a flip step and a solder ball placement step (S50) to flip over the substrate and place solder balls onto the backside of the substrate. Wherein, a solder ball placement device is mounted by hanging and moved by the robot arm to the working susceptor.

In the abovementioned embodiments, the devices are mounted by hanging and moved to the working susceptor to perform related works. Therefore, different packaging steps can be simultaneously performed in a panel substrate. For example, the chip attach step, the wire-bonding step, the molding step, etc. are simultaneously performed in different areas of a panel substrate. Besides, the method of the present invention may further comprise another step, such as an inspection step, a flip step, or a clean step to meet the requirement of the fabrication process.

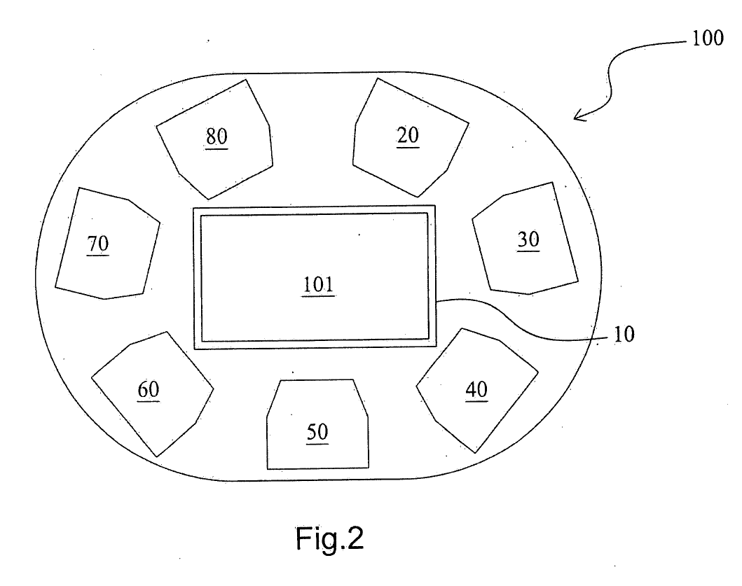

Referring to FIG. 2, in one embodiment, the electronic packaging apparatus comprises a working susceptor 10, a chip attach device 20, a wire-bonding device 30, a molding device 40 and a singulation device 60. In one embodiment, the electronic packaging apparatus of can further comprises a solder ball placement device 50, a mark device 70 and another device 80.

The working susceptor 10 is used for carrying a panel substrate 101. The chip attach device 20, wire-bonding device 30, molding device 40, solder ball placement device 50, singulation device 60, mark device 70 and another device 80 are hung in the nearby of the working susceptor 10 and moved by robot arms to the working susceptor 10 to simultaneously or non-simultaneously perform related works on specified areas of the panel substrate 101.

The chip attach device 20 is used for attaching a plurality of chips onto the panel substrate 101. The wire-bonding device 30 is used for electrically connecting the chips to the panel substrate 101 via a plurality of wires. The molding device 40 is used for encapsulating the chips and wires. The singulation device 60 is used for singulating the panel substrate 101 into a plurality of packages. The mark device 70 is used for marking the packages. The solder ball placement device 50 is used for placing solder balls onto the backside of the substrates 101.

In one embodiment, another device 80, such as a flip device, is mounted by hanging and moved by a robot arm to the working susceptor 10 to flip over the panel substrate 101. When the solder ball placement step (S50) can be perform without flipping over the panel substrate 101, the present invention is not limited to having to use the flip device. Obviously, the method of the present invention should also comprise appropriate steps to isolate and remove the process residues lest contamination occur.

In conclusion, the method of the present invention can adopt a panel substrate as the packaging substrate and simultaneously performs identical or different packaging steps in different areas of the panel substrate, whereby the product yield is increased and the cost is reduced. In the method of the present invention, the panel substrate is carried by the working susceptor, and the packaging devices are hung in the nearby of the working susceptor and moved by robot arms to the working susceptor, whereby the problems of substrate warpage and substrate transportation are overcome.

The embodiments described above are to demonstrate the technical contents and characteristics of the preset invention to enable the persons skilled in the art to understand make, and use the present invention. However, it is not intended to limit the scope of the present invention. Therefore, any equivalent modification or variation according to the spirit of the present invention is to be also included within the scope of the present invention.

What is claimed is:

1. An electronic packaging method, comprising:
a loading step: loading a substrate on a working susceptor;
a chip attach step: moving a chip attach device to said working susceptor to attach a plurality of chips onto said substrate;
a wire-bonding step: moving a wire-bonding device to said working susceptor to electrically connect said chips to said substrate via a plurality of wires;
a molding step: moving a molding device to said working susceptor to encapsulate said chips and said wires;
a singulation step: moving a singulation device to said working susceptor to singulate said substrate into a plurality of packages.

2. The electronic packaging method according to claim 1, further comprising a mark step of moving a mark device to said working susceptor to mark said packages.

3. The electronic packaging method according to claim 2, wherein said mark device is mounted by hanging and moved by a robot arm to said working susceptor to perform said mark step.

4. The electronic packaging method according to claim 1, wherein each of said chip attach device, said wire-bonding device, said molding device and said singulation device is mounted by hanging and moved by a robot arm to said working susceptor to perform related steps.

5. The electronic packaging method according to claim 1, wherein said chip attach step, said wire-bonding step, said molding step and said singulation step can perform simultaneously in different areas of said substrate.

6. The electronic packaging method according to claim 1, before said singulation step, further comprising a flipping step and a solder ball placement step: flipping over said substrate and placing solder balls onto a backside of said substrate, wherein a solder ball placement device is mounted by hanging and moved by a robot arm to said working susceptor to perform said solder ball placement step.

7. An electronic packaging device, comprising
a working susceptor used for carrying a substrate;
a chip attach device mounted by hanging and moved to said working susceptor to attach a plurality of chips onto said substrate;
a wire-bonding device mounted by hanging and moved to said working susceptor to electrically connect said chips to said substrate via a plurality of wires;
a molding device mounted by hanging and moved to said working susceptor to encapsulate said chips and said wires; and
a singulation device mounted by hanging and moved to said working susceptor to singulate said substrate into a plurality of packages.

8. The electronic packaging device according to claim 7, further comprising a mark device mounted by hanging and moved to said working susceptor to mark said packages.

9. The electronic packaging device according to claim 8, further comprising a robot arm used for moving said mark device.

10. The electronic packaging device according to claim 7, further comprising robot arms respectively arranged in said chip attach device, said wire-bonding device, said molding device and said singulation device and used for moving said chip attach device, said wire-bonding device, said molding device and said singulation device to said working susceptor to perform related steps.

11. The electronic packaging device according to claim 7, wherein said chip attach device, said wire-bonding device and said molding device can be moved simultaneously to different areas of said substrate on said working susceptor to perform related steps.

12. The electronic packaging device according to claim 7, further comprising a flip device used for flipping over said substrate, wherein said flip device is mounted by hanging and moved by a robot arm to said working susceptor to flip over said substrate.

13. The electronic packaging device according to claim 12, further comprising a solder ball placement device mounted by hanging and moved by a robot arm to said working susceptor to place solder balls onto a backside of said substrate.
